(19) United States
(12) Patent Application Publication
(10) Pub. No.: US 2023/0062275 A1
(43) Pub. Date: Mar. 2, 2023

(54) Electronic Control Unit with Slide-In Printed Circuit Board

(71) Applicant: Robert Bosch GmbH, Stuttgart (DE)

(72) Inventors: Ligor Manushi, Northville, MI (US); Jeff Reuter, Farmington, MI (US)

(21) Appl. No.: 17/462,530

(22) Filed: Aug. 31, 2021

(51) Int. Cl. H05K 5/00; H05K 1/02

(52) U.S. Cl. CPC H05K 5/006; H05K 1/021

(57) ABSTRACT

An improved electronic control unit for a motor vehicle comprises a printed circuit board in a one-piece bucket-style housing. The printed circuit board includes a heat-producing electrical component, and the housing includes a heat sink. During assembly of the electronic control unit, the printed circuit board is slid into the housing through an opening in the housing and along a pair of side rails. At the end of the side rails opposite the opening, there is a ramp that lifts the PCB towards the top wall of the housing, thus allowing the electrical component to thermally couple with the heat sink.

In the context of a motor vehicle, the term electronic control unit (ECU) refers to any computer embedded in the vehicle that controls one or more of the electrical systems or subsystems of the vehicle. Examples of different types of ECUs include engine control modules, transmission control modules, brake control modules, body control modules, and others.

An ECU typically consists of a printed circuit board (PCB) within a housing. There are two main types of ECU housing: bucket-style (also known as slide-in style) or sandwich-style. In a bucket-style housing, the housing is of one-piece construction with an opening at one end through which the PCB is inserted. In a sandwich-style housing, the housing is of two-piece construction, with the PCB secured between the housing portions. Each of the housing types has advantages and disadvantages, but conventionally bucket-style housings are lower-cost while offering less design flexibility than sandwich-style housings.

One area in which conventional bucket-style housings offer less design flexibility than sandwich-style housings is temperature regulation. For example, conventional bucket-style housings restrict the use of heat sinks. This in part because, with a conventional bucket-style housing, any thermal interface material (TIM) applied to a heat-producing component on the PCB would be rubbed off during insertion of the PCB into the housing. The improved ECU housing described herein overcomes this disadvantage without incurring significant cost—thus adding design flexibility while preserving the cost advantages of a bucket-style ECU housing.

### SUMMARY

One aspect of this disclosure is directed to an ECU for a motor vehicle. The ECU includes a printed circuit board (PCB) in a housing. Some components on the PCB may produce heat when operating. Examples of such heat-producing components include microprocessors, power supplies, memory chips, and others. If the temperature of a heat-producing component is left unregulated, it can overheat during normal operation, causing a temporary malfunction or permanent failure of the ECU.

Heat sinks may be used to help regulate the temperature of heat-producing components. A heat sink is made of a thermally conductive material, such as aluminum, and conducts heat away from the heat-producing component where it can dissipate in a fluid, such as the ambient air. A heat sink may include features such as fins to increase its surface area contacting the air (or other fluid) and thereby maximize heat dissipation.

A thermal interface material (TIM) may be used to enhance thermal coupling between a heat-producing component and a heat sink. A heat-producing component and a heat sink are thermally coupled when a thermally conductive path exists between them such that heat may be transferred from the heat-producing component to the heat sink. A TIM consists of a thermally conductive paste or gel that maximizes thermal coupling by filling any air gaps between the heat-producing component and heat sink. Preferably, a TIM is applied to the surface of a heat-producing component that will contact a heat sink before the PCB is inserted into the housing.

The housing of the ECU is preferably made of molded plastic in a one-piece bucket-style construction. The housing includes a pair of side rails to support the PCB and a heat sink positioned to thermally couple with a heat-producing component on the PCB. During assembly of the ECU, the PCB is slid into the housing through an opening at one end and along the side rails. At the end of each side rail opposite the opening, there is a ramp that lifts the PCB towards the top wall of the housing, thus allowing the electrical component to thermally couple with the heat sink. Locating the ramp at the end of the rails opposite the opening prevents the TIM from being rubbed or scraped off on the housing prior to making contact with the heat sink.

The above aspects of this disclosure and other aspects will be explained in greater detail below with reference to the attached drawings.

### BRIEF DESCRIPTION OF THE DRAWINGS

FIG. 1 is a sectioned side view of an improved ECU in its assembled state showing the internal structure of the ECU.

FIG. 2 is a front view of an improved ECU with the PCB hidden from view showing the details of the ECU housing.

FIG. 3 is a perspective view of an improved ECU in its assembled state showing the external structure of the ECU.

FIG. 4 is a top view of an improved ECU in its assembled state with the heat sink bidden from view.

FIG. 5 is a zoomed-in view of a portion of the interior of the ECU with the PCB hidden from view.

FIG. 6 is a zoomed-in view of a tooth on the ECU connector.

### DETAILED DESCRIPTION

The illustrated embodiments are disclosed with reference to the drawings. However, it is to be understood that the disclosed embodiments are intended to be merely examples that may be embodied in various and alternative forms. The figures are not necessarily to scale and some features may be exaggerated or minimized to show details of particular components. The specific structural and functional details disclosed are not to be interpreted as limiting, but as a representative basis for teaching one skilled in the art how to practice the disclosed concepts.

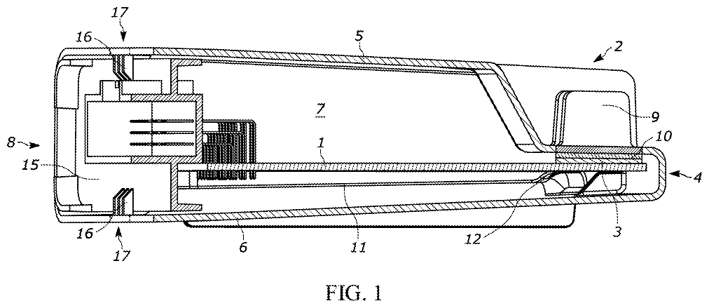

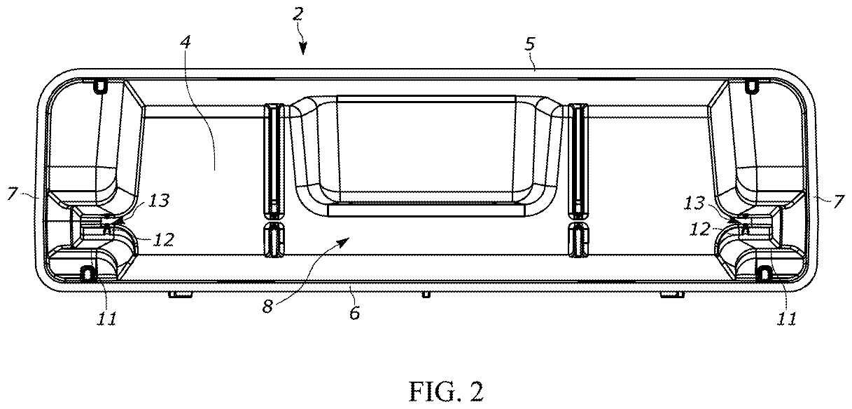

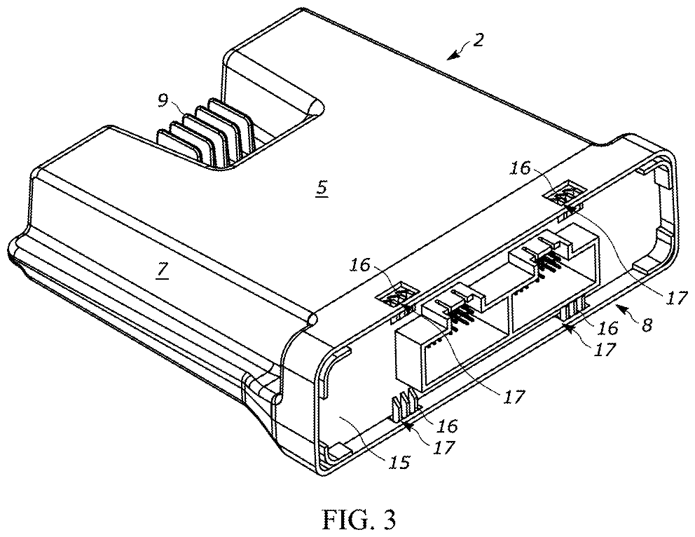

As shown in FIGS. 1 through 6, which provide various views of the same disclosed embodiment, an improved ECU consists of a PCB 1 in a housing 2. The PCB 1 contains ECU circuitry. In general, ECU circuitry includes at least a processor, memory, and a data interface allowing the ECU to control one or more of the electrical systems or subsystems of the vehicle. In the disclosed embodiment, the ECU is a gateway module that manages internal communication between modules on the vehicle and external over-the-air communication, but the improvements to an ECU housing described herein could be applicable to any type of ECU within or outside the context of a motor vehicle. In the disclosed embodiment, the PCB 1 includes a microprocessor 3 and other components, including random access memory (RAM), non-volatile data storage, Ethernet switch circuitry, and a data interface (other components not shown). At least the microprocessor 3 is a heat-producing component and must be used with a heat sink or other means of temperature regulation to avoid malfunction or failure.

The housing 2 is preferably of one-piece molded plastic construction but could be of any suitable material. It consists, generally, of a base 4, a top wall 5, a bottom wall 6, and two side walls 7, with an opening 8 at one end. The base 4 is the portion of the housing that is opposite the opening and from which the walls extend. The base 4 can be flat, curved, or irregular in profile. The walls 5-7 are the portions of the housing 2 that extend away from the base 4 towards the opening 8. Together the walls 5-7 define and surround the opening 8. The walls 5-7 can be flat, curved, or irregular in profile. Adjacent walls 5-7, or one or more walls 5-7 and the base 4, can be merged into one another such that there is no clear edge between them. The top wall 5 is the wall that faces the surface of the PCB that contains the microprocessor 3, i.e. the top side of the PCB. The bottom wall 6 is opposite the top wall 5 and faces the underside of the PCB. The top wall 5 and bottom wall 6 of the housing are connected via the side walls 7.

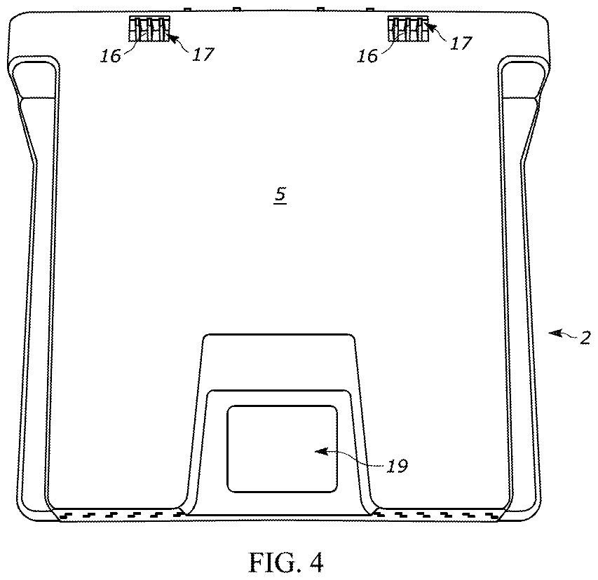

On the top wall 5 of the housing 2 a heat sink 9 is attached. The heat sink 9 is made of a thermally conductive material, such as aluminum, and may include features, such as fins, to increase its surface area. In the disclosed embodiment, the heat sink 9 is attached to the outside of the housing 2. Alternatively, the heat sink 9 can be attached inside the housing 2. The heat sink 9 may be attached to the housing 2 via adhesive, heat staking, retention features, press-in, or overmolding. In the disclosed embodiment, the heat sink 9 thermally couples with the microprocessor 3 through an aperture 19 in the housing 2. (See FIG. 4.) A TIM 10 is used to enhance thermal coupling between the microprocessor 3 and heat sink 9. The TIM 10 is applied to the microprocessor 3 prior to insertion of the PCB 1 into the housing 2. Preferably, the TIM 10 is applied to only a portion of the top surface of the microprocessor 3, so that as the microprocessor 3 contacts the heat sink 9, the TIM 10 smears to cover substantially the whole top surface of the microprocessor 3.

On each side wall 7 of the housing 2 is a rail 11. The rails 11 extend from the opening 8 to a slot 13 at the base 4. During assembly of the ECU, the rails 11 guide and support the PCB 1 as it is inserted into the housing 2 through the opening 8. The rails 11 are angled slightly towards to the top wall 5 such that the distance between the rails 11 and the top wall 5 is less near the base 4 than near the opening 8. This allows for easy insertion of the PCB 1 into the housing 2 while also guiding the PCB 2 towards its final location. At the end of the rails 11 opposite the opening 8, each rail 11 forms a ramp 12 that lifts the PCB 1 further towards the top wall 5 of the housing 2, thus allowing the microprocessor 3 to thermally couple with the heat sink 9. Locating the ramp 12 at the end of the rail 11 opposite the opening 8 prevents the TIM 10 (which is applied to the microprocessor 3 prior to inserting the PCB 1 into the housing 2) from being rubbed or scraped off prior to making contact with the heat sink 9.

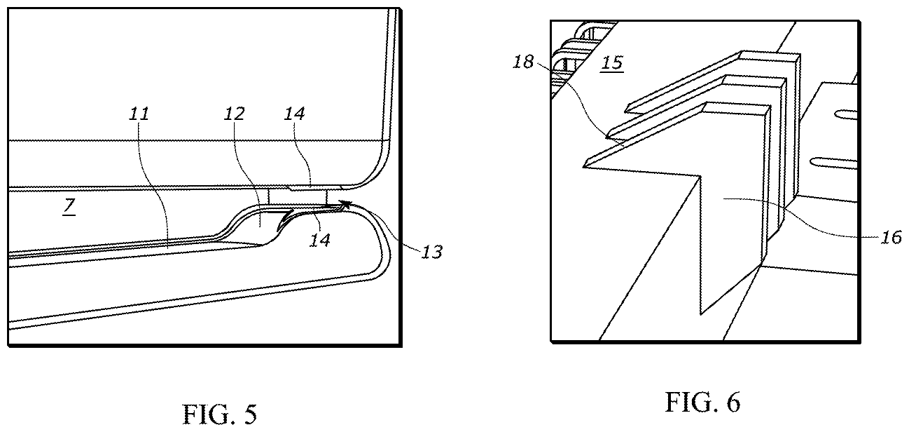

Upon reaching the top of the ramp 12, the PCB 1 mates with the slot 13 at the base 4 of the housing 2. The slot 13 contains compression features such as crush ribs 14 to grip the PCB 1. (See FIG. 5.)

At the end of the PCB 1 opposite the slot 13, a connector 15 mounted on the PCB 1 includes one or more teeth 16 (see FIG. 6) that mate with holes 17 in the housing 2. The connector 15, including its teeth 16, are made of a rigid plastic. The sides of the teeth 16 facing towards the PCB 1 each include an angled surface 18, allowing the connector 15 to be inserted into the opening 8 until the teeth 16 mate with the holes 17. The sides of the teeth 16 facing away from the PCB 1 are perpendicular to the plane of the holes 17, thus—upon mating with the holes 17—locking the PCB 1 into the housing 2. Accordingly, the PCB 1 is fastened securely to the housing 2 without the need of bolts or adhesives.

While exemplary embodiments are described above, it is not intended that these embodiments describe all possible forms of the disclosed apparatus and method. Rather, the words used in the specification are words of description rather than limitation, and it is understood that various changes may be made without departing from the spirit and scope of the disclosure as claimed. The features of various implementing embodiments may be combined to form further embodiments of the disclosed concepts.

1. An electronic control unit comprising:
a printed circuit board containing electronic control unit circuitry, the circuitry including at least one heat-producing component;
a one-piece molded plastic bucket-style housing including a base, a top wall, a bottom wall, two side walls, and a rail adjacent to each side wall, the rails being integral to the housing and the walls defining an opening in the housing opposite the base; and
a heat sink attached to the top wall of the housing,
wherein each of the rails defines at its end opposite the opening a ramp adapted to, as the printed circuit board is inserted through the opening and slid along the rails towards the base, lift the printed circuit board towards the top wall such that the heat-producing component thermally couples with the heat sink.

2. The electronic control unit of claim 1 further comprising a thermal interface material disposed between the heat-producing component and the heat sink.

3. (canceled)

4. The electronic control unit of claim 2, wherein the heat sink is attached inside of the housing.

5. The electronic control unit of claim 4, wherein the printed circuit board is secured to the housing without bolts or adhesives.

6. The electronic control unit of claim 2, wherein the heat sink is attached outside of the housing and the heat-producing component thermally couples with the heat sink through an aperture in the housing.

7. The electronic control unit of claim 6, wherein the printed circuit board is secured to the housing without bolts or adhesives.

8. A method for assembling an electronic control unit comprising:
inserting a printed circuit board that includes a heat-producing component into a one-piece molded plastic bucket-style housing with a heat sink attached to a top wall of the housing, wherein the printed circuit board is inserted through an opening in the housing defined by the top wall, a bottom wall, and two side walls of the housing;
sliding the printed circuit board along a pair of rails disposed on the side walls, the rails being integral to the housing and defining ramps at their ends opposite the opening;
lifting the printed circuit board towards to the top wall using the ramps until the heat-producing element becomes thermally coupled with the heat sink.

9. The method of claim 8 further comprising applying a thermal interface material to the heat-producing component.

10. The method of claim 9 wherein the thermal interface material is applied to the heat producing component prior to inserting the printed circuit board into the housing.

11. The method of claim 10, wherein the thermal interface material is applied to only a portion of a top surface of the heat-producing component, and wherein the thermal interface material smears against the heat sink as the heat-producing element becomes thermally coupled with the heat sink.

12. (canceled)

13. The method of claim 11, wherein the heat sink is attached inside of the housing.

14. method of claim 13 further comprising securing the printed circuit board to the housing without bolts or adhesives.

15. The method of claim 11, wherein the heat sink is attached outside of the housing and the heat-producing component thermally couples with the heat sink through an aperture in the housing.

16. The method of claim 15 further comprising securing the printed circuit board to the housing without bolts or adhesives.
